(19) United States
(12) Patent Application Publication
(10) Pub. No.: US 2026/0113972 A1
(43) Pub. Date: Apr. 23, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: CHING-PAI HSU, NEW TAIPEI CITY (TW); TSUNG-YU CHIANG, NEW TAIPEI CITY (TW)

(21) Appl. No.: 19/051,223

(22) Filed: Feb. 12, 2025

Related U.S. Application Data
(60) Provisional application No. 63/710,616, filed on Oct. 23, 2024.

(51) Int. Cl. H10D 30/00; H10D 30/01; H10D 62/10; H10D 64/66

(52) U.S. Cl. CPC H10D 30/509; H10D 30/0195; H10D 62/116; H10D 64/675

(57) ABSTRACT

A semiconductor structure is provided. The semiconductor structure includes channel members disposed above a substrate, a gate structure wrapping around the channel members, inner spacers adjacent to the gate structure, and a source/drain feature abutting the channel members. One of the inner spacers includes a middle dielectric portion and a shield dielectric portion that covers surfaces of the middle dielectric portion. The dielectric constant of the shield dielectric portion is greater than the dielectric constant of the middle dielectric portion.

### CROSS-REFERENCE TO RELATED APPLICATION(S)

This application claims the benefit of U.S. Provisional Application No. 63/710,616, filed Oct. 23, 2024, the entire disclosure of which is incorporated by reference herein.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Recently, multi-gate transistors have been introduced in an effort to improve gate control by increasing gate-channel coupling, reduce OFF-state current and reduce short-channel effects (SCEs). One such multi-gate transistor that has been introduced is the fin field-effect transistor (FinFET). The FinFET gets its name from the fin-shaped structure which extends from a substrate on which it is formed, and which is used to form the FET channel. A further type of multi-gate transistor, introduced in part to address performance challenges associated with some configurations of FinFETs, is a wrap-around gate device, such as a gate-all-around (GAA) transistor. The wrap-around gate device gets its name from the gate structure which extends completely around the channel region, providing access to the channel on four sides. The channels of the wrap-around gate device have a plurality of horizontal nanowires, nanosheets, and/or nano-strips spaced vertically. The wrap-around gate devices are compatible with conventional complementary metal-oxide-semiconductor (CMOS) processes and their structure allows them to be aggressively scaled while maintaining gate control and mitigating SCEs.

In multi-gate devices, such as wrap-around gate devices, inner spacers have been used to reduce capacitance and leakage between gate structures and source/drain features. Although current methods for forming wrap-around gate devices with inner spacers have been generally adequate for their intended purposes, they continue to face challenges in terms of both device fabrication and performance, and are not satisfactory in every respect. For example, the etching processes such as the process for channel release and the process for source/drain formation may damage the inner spacers.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart illustrating a method for forming a semiconductor structure from a workpiece, in accordance with some embodiments of the present disclosure.

FIG. 2 is a fragmentary perspective view of a semiconductor structure at an intermediate stage, in accordance with some embodiments of the present disclosure.

FIGS. 3A, 3B, 3C, 3D, 3E, 3F, 3G, 3H, 3I, 3J, 3K, 3L, 3M, 3N, and 3O are fragmentary cross-sectional views illustrating the manufacturing of a semiconductor structure at various intermediate stages, in accordance with some embodiments of the method in FIG. 1.

FIG. 4 is energy dispersion X-ray spectrum (EDX) analysis of the relative concentrations of several atomic species versus positions of the inner spacers of exemplary structure, in accordance with some embodiments.

FIG. 5A, FIG. 5B, and FIG. 5C are fragmentary cross-sectional views illustrating semiconductor structures at an intermediate stage after forming the middle dielectric portions of the inner spacers, in accordance with some embodiments of the present disclosure.

FIG. 6A, FIG. 6B, and FIG. 6C are fragmentary cross-sectional views illustrating semiconductor structures at an intermediate stage after forming the inner spacers, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure is generally related to semiconductor structures and method for manufacturing the same, and more particularly to inner spacer formation during fabricating of multi-gate semiconductor structures (such as wrap-around gate transistor). In a wrap-around gate transistor, the gate of the transistor is made all around the channel such that the channel is surrounded or wrapped by the gate. Such a transistor has the advantage of improving the electrostatic control of the channel by the gate, which also mitigates leakage currents. A wrap-around gate transistor includes inner spacers and outer gate sidewall spacers (or simply referred to as gate spacers). Inner spacers are typically formed by an additional process to gate spacers. The inner spacers are formed between the channel layers, and used to reduce capacitance and leakage between gate structures and source/drain features. An object of the present disclosure is to provide robust inner spacers and fabrication method. The inner spacers of the embodiments have the advantages of preventing etch damage and reducing parasitic capacitance between the gate structures and the source/drain features, thereby improving the reliability and electrical performance of the semiconductor structure. A source/drain feature may refer to a source or a drain, individually or collectively dependent upon the context.

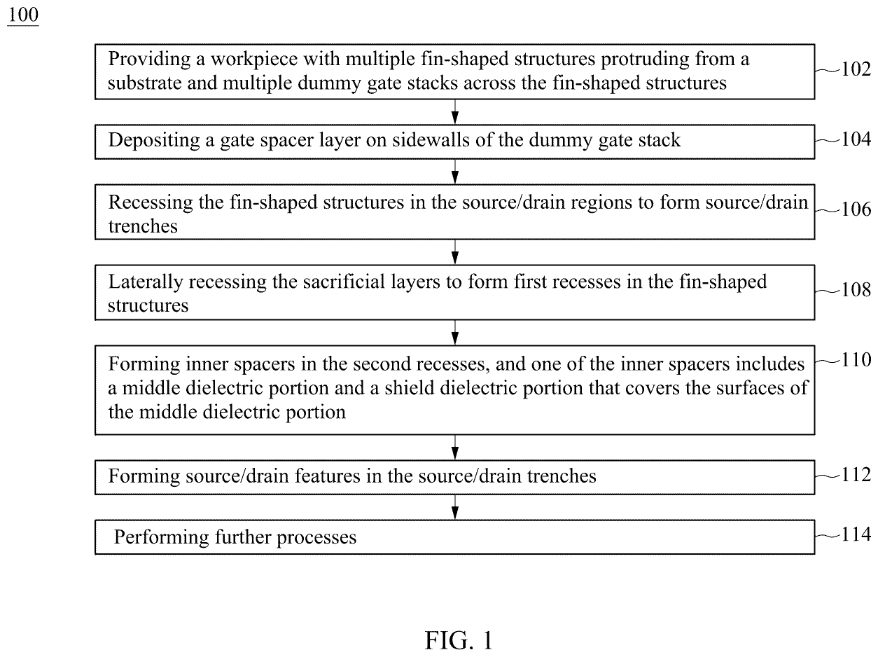

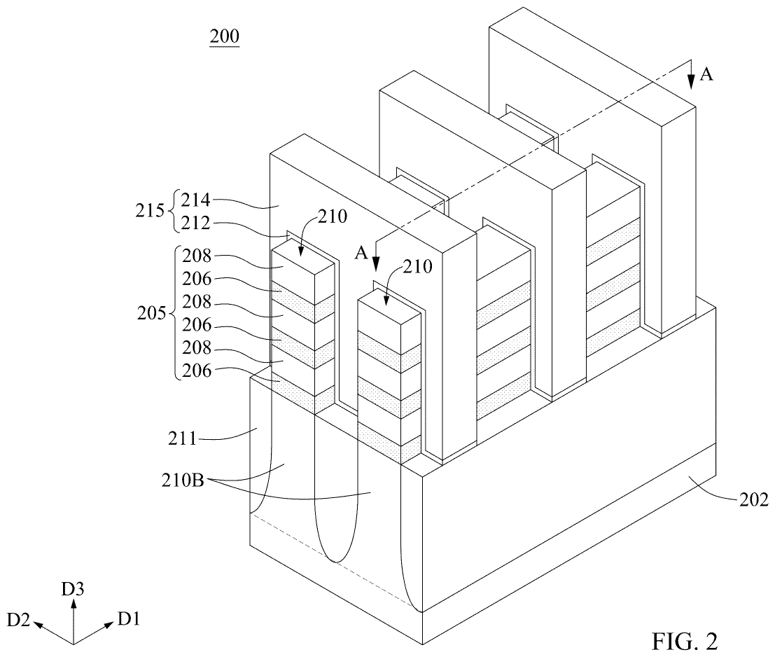

The various aspects of the present disclosure will now be described in more detail with reference to the figures. In that regard, FIG. 1 is a flowchart illustrating a method 100 for forming a semiconductor structure from a workpiece according to an embodiment of the present disclosure. FIG. 2 is a fragmentary perspective view of a semiconductor structure at an intermediate stage, in accordance with some embodiments. A nanosheet field-effect transistor is exemplary to illustrate a semiconductor structure in some embodiments; however, the disclosure is not limited to the nanosheet field-effect transistor.

Method 100 is merely an example and is not intended to limit the present disclosure to what is explicitly illustrated in method 100. Additional steps can be provided before, during, and after method 100, and some steps described can be replaced, eliminated, or rearranged around for additional embodiments of the method. Not all steps are described herein in detail for reasons of simplicity. Method 100 is described below in conjunction with FIG. 2, which is a perspective view of a workpiece 200. Because the workpiece 200 will be fabricated into a semiconductor structure, the workpiece 200 may be referred to herein as a semiconductor structure 200. In addition, the D1, D2 and D3 directions in FIGS. 2, 3A-3O, 5A-5C and 6A-6C are perpendicular to one another. Throughout the present disclosure, like reference numerals denote like features, unless otherwise specified.

In some embodiments, as shown in FIG. 2, the semiconductor structure 200 includes fin-shaped structures 210 protruding from a substrate 202. Each of the fin-shaped structures 210 includes sacrificial layers 206 and channel layers 208 alternately stacked over the substrate 202. Multiple dummy gate stacks 215 extend across the fin-shaped structures 210 and are oriented lengthwise along the D2 direction. In some embodiments, the extending direction of the fin-shaped structures 210 is perpendicular to the extending direction of the dummy gate stacks 215. Source/drain regions are formed on opposing sides of the dummy gate stacks 215. The channel layers 208 over the substrate 202 are formed between the source/drain regions. Isolation features 211 are formed on opposing sides of the fin-shaped structures 210. The isolation features 211 may be leveled with the top surfaces of the fin-shaped bases 210B. Each of the dummy gate stacks 215 may include a dummy dielectric layer 212 on the fin-shaped structures 210 and a dummy electrode layer 214 on the dummy dielectric layer 212.

FIG. 2 further illustrates the reference cross-section that is used in later figures. Cross-section A-A is along a longitudinal axis of a fin-shaped structure 210 (e.g., in direction D1), for example, perpendicular to the direction (e.g., direction D2) along a longitudinal axis of a dummy gate stack 215. Subsequent figures refer to the reference cross-section A-A for clarity.

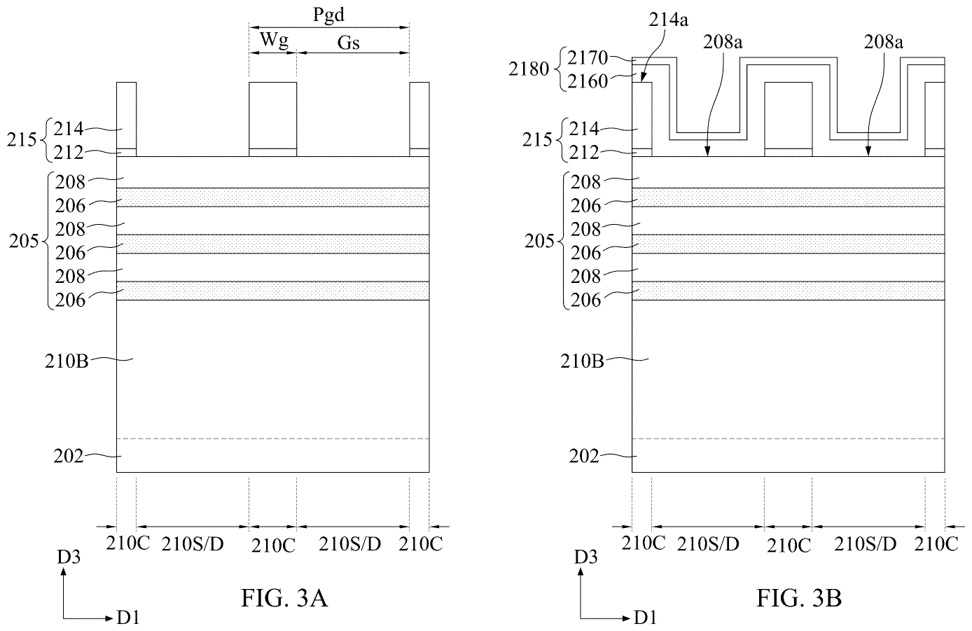

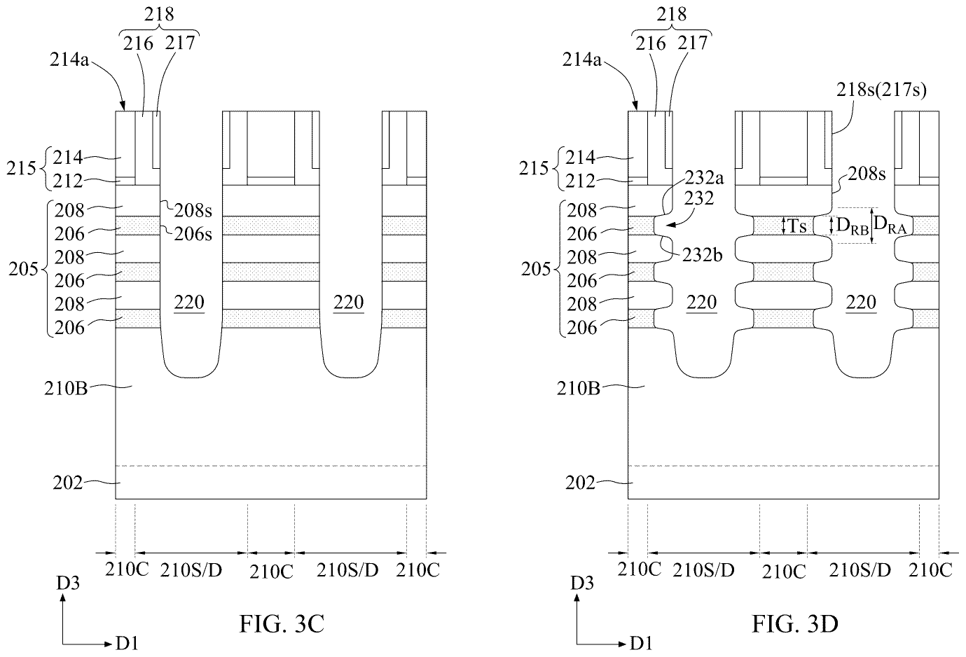

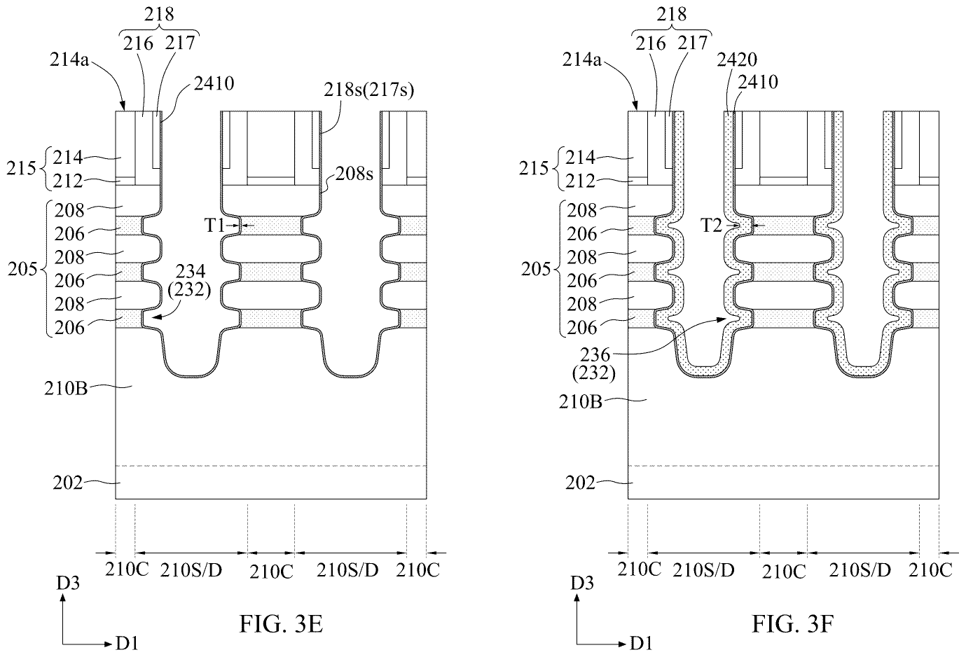

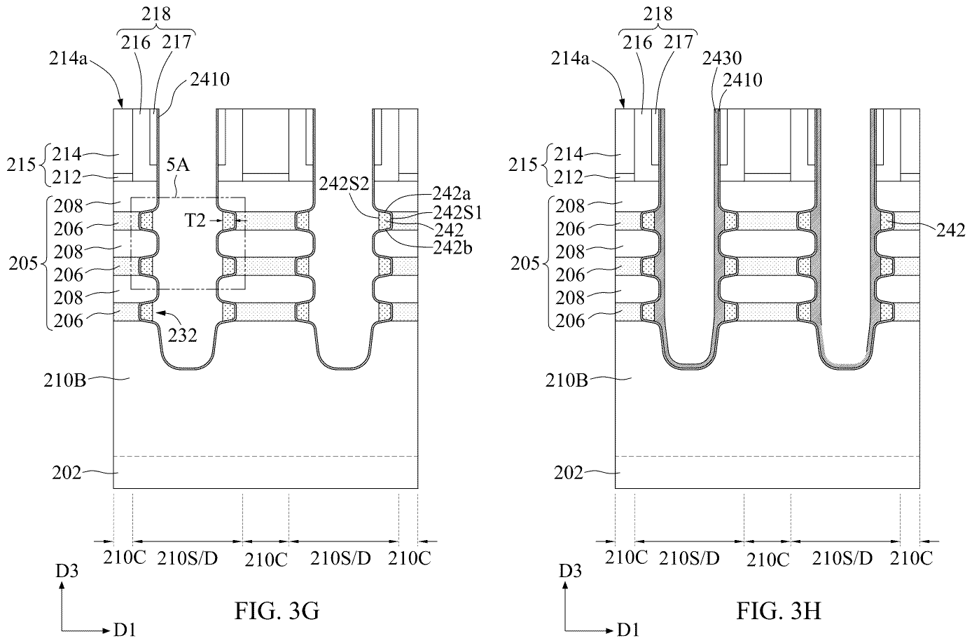

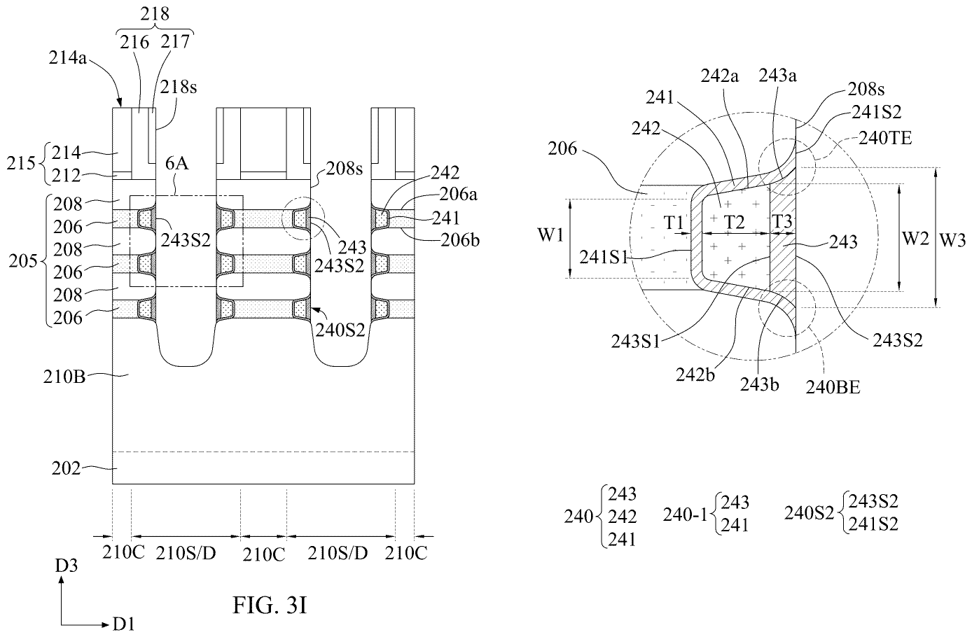

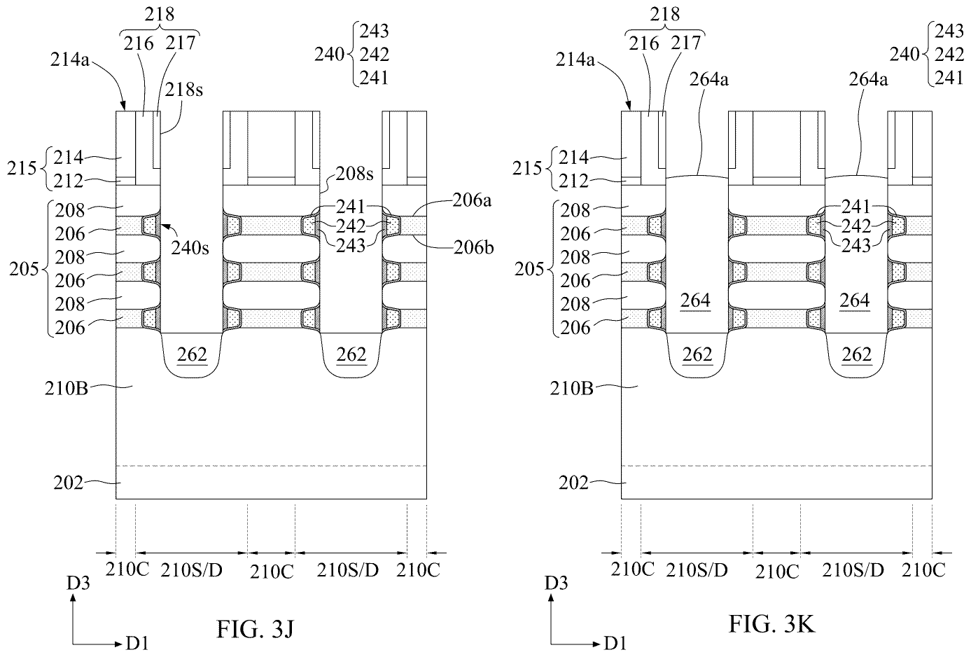

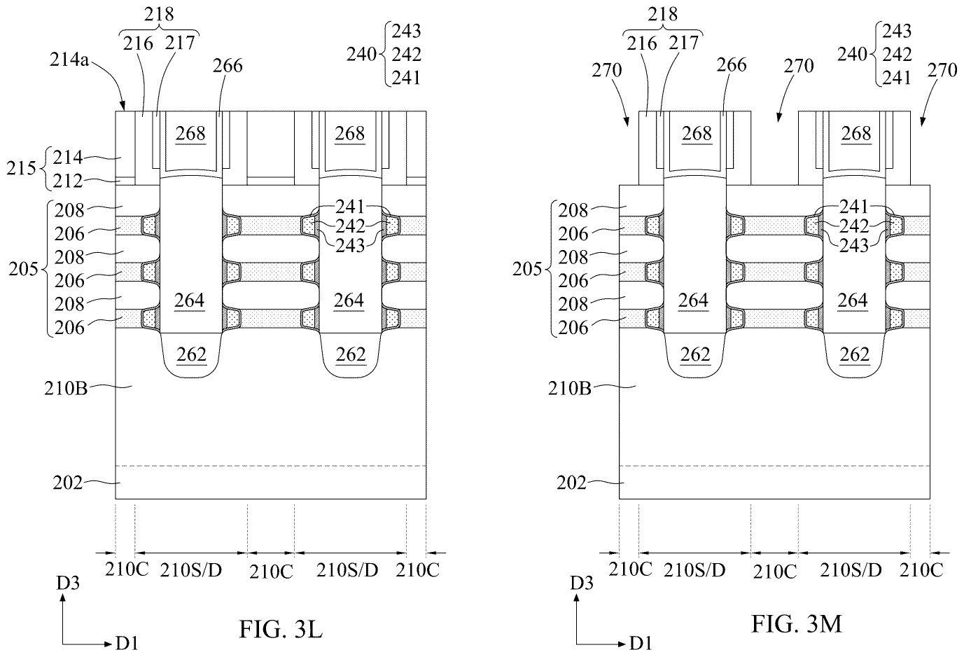

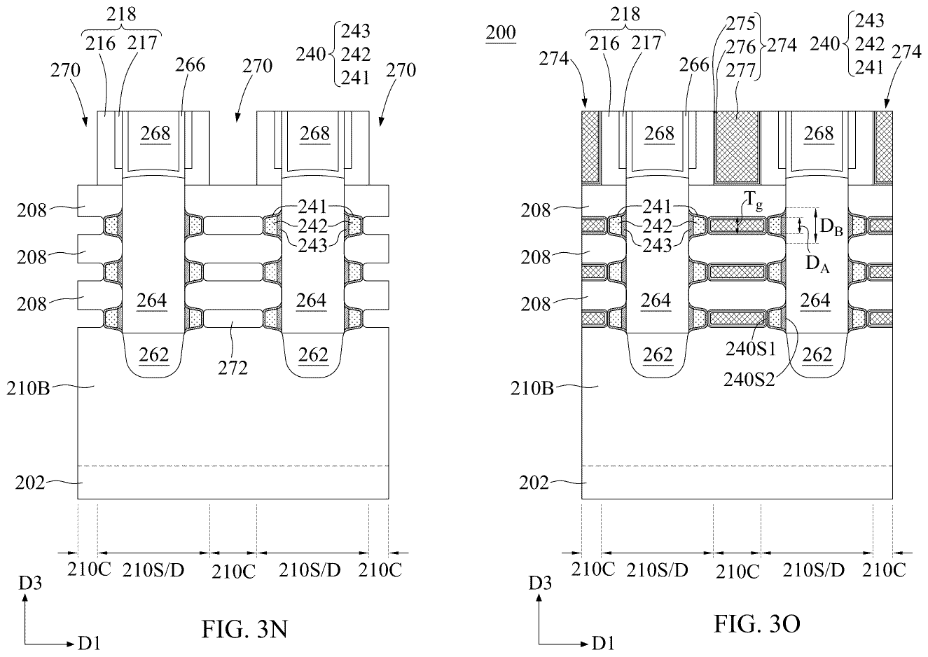

FIGS. 3A-3O are fragmentary cross-sectional views illustrating the manufacturing of a semiconductor structure at various intermediate stages, in accordance with some embodiments of the method 100 in FIG. 1. FIG. 3A is a cross-sectional view taken along cross-section A-A in FIG. 2, which extends along the lengthwise direction of a fin-shaped structure 210. Referring to FIGS. 1, 2, and 3A, method 100 includes a block 102 where a workpiece 200 is provided with multiple fin-shaped structures 210 protruding from a substrate 202, and multiple dummy gate stacks 215 are positioned across the fin-shaped structures 210. In some embodiments, the fin-shaped structures 210 are oriented lengthwise along the D1 direction, and the dummy gate stacks 215 are oriented lengthwise along the D2 direction. The D1 direction may be perpendicular to the D2 direction. The fin-shaped structures 210 may include two fins, one in an n-type region (where n-type transistors will be formed) and the other in a p-type region (wherein p-type transistors will be formed). Alternatively, the fin-shaped structures 210 may include two fins, both located in n-type regions or both in p-type regions.

In some embodiments, the substrate 202 may be a semiconductor substrate such as a silicon (Si) substrate. The substrate 202 may include various doping configurations depending on design requirements as is known in the art. In embodiments where the semiconductor device is p-type, an n-well (not shown) may be formed on the portion of the substrate 202 in the p-type region. In some implementations, the n-type dopant for forming the n-well may include phosphorus (P) or arsenic (As). In embodiments where the semiconductor device is n-type, a p-well may be formed on the portion of the substrate 202 in the n-type region. In some implementations, the p-type dopant for forming the p-well may include boron (B) or gallium (Ga). The suitable doping method may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may include an epitaxial layer (epi-layer), may be strained for performance enhancement, may include a silicon-on-insulator (SOI) or a germanium-on-insulator (GeOI) structure, and/or may have other suitable enhancement features.

In some embodiments, each of the fin-shaped structures 210 includes alternating layers atop a fin-shaped base 210B. The formation of the fin-shaped structures 210 may include depositing a lamination (not shown) on the substrate 202 in an epitaxial growth process and patterning the lamination and a top portion of the substrate 202 to form multiple stacks 205. Each of the stacks 205 includes a fin-shaped structure 210. Since the fin-shaped base 210B is formed by patterning a top portion of the substrate 202, the fin-shaped base 210B may still be considered a top part of the substrate 202 as the context requires.

The stack 205 includes sacrificial layers 206 interleaved with channel layers 208. The sacrificial layers 206 and the channel layers 208 include different material compositions. In some embodiments, the sacrificial layers 206 include a semiconductor composition, such as silicon germanium (SiGe) or another suitable semiconductor material. In some embodiments, the sacrificial layers 206 include a dielectric composition, such as oxide or another suitable interposer material, and the sacrificial layers 206 can be referred to as sacrificial dielectric interposers. In some embodiments, the channel layers 208 include semiconductor composition silicon (Si). Although three layers of the sacrificial layers 206 and three layers of the channel layers 208 are alternately arranged in the exemplary embodiment, this is for illustrative purposes only, and is not intended to be limiting beyond what is specifically recited in the claims. It can be appreciated that any number of epitaxial layers (i.e. the sacrificial layers 206 and the channel layers 208) may be formed in the stack 205. The number of layers depends on the desired number of channel members for the semiconductor structure 200. In some embodiments, the number of channel layers 208 is between 1 and 20.

In some embodiments, all of the sacrificial layers 206 may have a substantially uniform thickness between about 3 nm and about 10 nm, and all of the channel layers 208 may have a substantially uniform thickness between about 3 nm and about 15 nm. The thicknesses of the sacrificial layer 206 and the channel layers 208 may be the same or different. As described in more detail below, the channel layers 208 or parts thereof may serve as channel members for a subsequently-formed multi-gate device, and the thickness of the channel layers 208 can be determined based on device performance considerations. In some embodiments, the sacrificial layers 206 in the channel region are eventually removed and serve to define a vertical distance between adjacent channel layers 208 of a subsequently-formed multi-gate device. The thickness of the sacrificial layers 206 is determined based on device performance considerations.

The layers in the stack 205 may be deposited using a molecular beam epitaxy (MBE) process, a vapor phase deposition (VPE) process, and/or another suitable epitaxial growth process. Therefore, the stack 205 is also referred to as the epitaxial stack 205. As stated above, in at least some embodiments, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free. That is, the sacrificial layers 206 and the channel layers 208 may have an extrinsic dopant concentration from approximately 0 cm⁻³ to 1×10¹⁷ cm⁻³. No intentional doping is performed during the epitaxial growth processes for forming the sacrificial layers 206 and the channel layers 208.

In some embodiments, the fin-shaped structures 210 may be patterned from the stack 205 and the substrate 202 using a lithography process and an etch process. The lithography process may include photoresist coating (such as spin-on coating), soft baking, mask aligning, exposure, post-exposure baking, photoresist developing, rinsing, drying (such as spin-drying and/or hard baking), other suitable lithography techniques, and/or combinations thereof. In some embodiments, the etch process may include dry etching (such as reactive ion etching (RIE)), wet etching, and/or another etching method. In some implementations, double-patterning or multi-patterning processes may be used to define fin-shaped structures 210 that have, for example, pitches smaller than what is otherwise obtainable using a single, direct photolithography process. For example, in one embodiment, a material layer (not shown) is formed over the substrate 202 and patterned using a photolithography process. Spacers are formed alongside the patterned material layer using a self-aligned process. The material layer is then removed, and the remaining spacers, or mandrels, may then be used to pattern the fin-shaped structures 210 by etching the stack 205 and a top portion of the substrate 202.

In addition, the workpiece 200 (or semiconductor structure 200) includes isolation features 211 (FIG. 2) deposited in trenches between opposing sidewalls of two adjacent fin-shaped structures 210. In some embodiments, the isolation features 211 are formed in the trenches to isolate the fin-shaped structures 210 from a neighboring fin-shaped structure. The isolation features 211 may also be referred to as shallow trench isolation (STI) features 211. In some exemplary methods for forming the isolation features 211, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric material, another suitable material, and/or combinations thereof. In various examples, the dielectric layer may be deposited by a chemical vapor deposition (CVD) process, a subatmospheric CVD (SACVD) process, a flowable CVD process, a spin-on coating process, and/or another suitable process. The deposited dielectric material is then thinned and planarized, for example by a chemical mechanical polishing (CMP) process. The planarized dielectric layer is further recessed or pulled back by a dry etching process, a wet etching process, and/or a combination thereof to form the STI features 211. The fin-shaped structures 210 rise above the STI features 211 after recessing the planarized dielectric layer. The recessed top surfaces of the STI features 211 may be leveled with the top surfaces of the fin-shaped bases 210B.

After the fin-shaped structures 210 are defined, multiple dummy gate stacks 215 are formed over the fin-shaped structures 210. The dummy gate stack 215 may include a dummy dielectric layer 212 and a dummy electrode layer 214 on the dummy dielectric layer 212. The formation of the dummy gate stacks 215 may include deposition of layers of the dummy gate stack 215 and patterning of these layers. In some embodiments, a dummy dielectric material, a dummy electrode material, and a gate-top hard mask layer (not shown) may be blanketly deposited over the substrate 202, covering the fin-shaped structures 210 and the isolation features 211.

In some embodiments, the dummy dielectric material may be formed on the fin-shaped structures 210 using a CVD process, an atomic layer deposition (ALD) process, an oxygen plasma oxidation process, or another suitable process. The dummy dielectric material may include silicon oxide or another suitable dielectric material. In some embodiments, the dummy electrode material may be deposited over the dummy dielectric material using a CVD process, an ALD process, or another suitable process. The dummy electrode material may include polysilicon. For patterning purposes, the gate-top hard mask layer may be deposited on the dummy electrode material using a CVD process, an ALD process, or another suitable process. The dummy electrode material and the dummy dielectric material may then be patterned to form the dummy gate stacks 215 using the gate-top hard mask layer as a patterning mask. For example, the patterning process may include a lithography process (such as photolithography or e-beam lithography), which may further include photoresist coating (such as spin-on coating), soft baking, mask aligning, exposure, post-exposure baking, photoresist developing, rinsing, drying (such as spin-drying and/or hard baking), another suitable lithography technique, and/or combinations thereof. In some embodiments, the etching process may include dry etching (such as RIE etching), wet etching, and/or another etching method.

The dummy gate stacks 215 are formed over respective channel regions 210C of the fin-shaped structures 210. In some embodiments, a gate replacement process (or gate-last process) is adopted, wherein the dummy gate stacks 215 serve as a placeholder to undergo various processes and are to be removed and replaced by the functional gate structures. At intersections of the fin-shaped structures 210 and the functional gate structures, transistors are formed. In the exemplary embodiment, with the dummy gate stacks 215 formed over the fin-shaped structures 210, the fin-shaped structures 210 are divided into channel regions 210C underlying the dummy gate stacks 215 and source/drain regions 210S/D between the channel regions 210C. As shown in FIG. 3A, a channel region 210C is disposed between two source/drain regions 210S/D along the D1 direction. In addition, the dummy gate stacks 215 are separated from each other by a gate spacing GS in the D1 direction. The gate width Wg of the dummy gate stack 215 and the pitch Pgd between adjacent dummy gate stacks 215 in the D1 direction are also depicted in FIG. 3A. The dummy gate stacks 215 formed in the channel regions 210C may have a uniform gate width Wg.

Referring to FIG. 1 and FIG. 3B, method 100 includes a block 104 where a gate spacer layer 218 is deposited on sidewalls of the dummy gate stack 215. The gate spacer layer 218 may be a single layer or a multi-layer. In some embodiments, one layer of the gate spacer layer 218 may include silicon carbonitride, silicon oxycarbide, silicon oxycarbonitride, or silicon nitride. The gate spacer layers 218 may be deposited over the dummy gate stacks 215 using processes such as a CVD process, a subatmospheric CVD (SACVD) process, an ALD process, or another suitable process.

In some embodiments, the gate spacer layer 218 includes a first gate spacer 216 and a second gate spacer 217 disposed over the first gate spacer 216, as shown in FIG. 3B. The first gate spacer 216 may include silicon oxynitride and the second gate spacer 217 may include silicon nitride. The formation of the gate spacer layer 218 may include conformal depositions of a first gate spacer material (not shown) and a second gate spacer material (not shown) on the first gate spacer material, followed by patterning of these gate spacer materials. The term “conformally” may be used herein for ease of description of a layer having substantially uniform thickness over various regions. In some embodiments, the patterning process may include removing excess portions of the second gate spacer material and the first gate spacer material that include top portions over the top surfaces 214a of the dummy electrode layers 214 and bottom portions over the topmost channel layer 208. As shown in FIG. 3B, remaining portions of the first gate spacer material and the second gate spacer material may be referred to as the first gate spacer 216 and the second gate spacer 217, respectively. In some embodiments, after the patterning process, the top surfaces 214a of the dummy electrode layers 214 and the top surface 208a of the topmost sacrificial layer 208 are exposed. The gate spacer layers 218 may also be referred to as gate spacers 218.

Referring to FIG. 1 and FIG. 3C, method 100 includes a block 106 where the fin-shaped structures 210 in the source/drain regions 210S/D are recessed to form source/drain trenches 220. In some embodiments, the source/drain regions 210S/D that are not covered by the dummy gate stack 215 and the gate spacer layer 218 are etched by a dry etch process or another suitable etching process to form the source/drain trenches 220. For example, the dry etch process may utilize an oxygen-containing gas, a fluorine-containing gas (such as CF₄, SF₆, CH₂F₂, CHF₃, and/or C₂F₆), a chlorine-containing gas (such as Cl₂, CHCl₃, CCl₄, and/or BCl₃), a bromine-containing gas (such as HBr and/or CHBr₃), an iodine-containing gas, another suitable gas, plasmas, and/or combinations thereof. In some embodiments, the fin-shaped structures 210 are recessed to expose the sidewalls 206s of the sacrificial layers 206 and the sidewalls 208s of the channel layers 208. In some implementations, the source/drain trenches 220 extend below the stack 205 into the fin-shaped base 210B.

Referring to FIG. 1 and FIG. 3D, method 100 includes a block 108 where the sacrificial layers 206 are laterally recessed to form several recesses 232 in the fin-shaped structures 210. In some embodiments, operation at block 108 may include selective and partial removal of the sacrificial layers 206 to form the recesses 232 between adjacent channel layers 208. In some embodiments, the sacrificial layers 206 exposed in the source/drain trenches 220 are selectively and laterally etched to form the recesses 232 while the gate spacer layer 218, the exposed portion of the fin-shaped base 210B (the substrate 202) and the channel layers 208 are substantially unetched. As shown in FIG. 3D, the recesses 232 at opposite ends of each of the sacrificial layers 206 are separated from each other along the first direction D1.

In an embodiment where the channel layers 208 consist essentially of silicon (Si) and the sacrificial layers 206 consist essentially of silicon germanium (SiGe), the selective recess of the sacrificial layers 206 may be performed using a selective wet etch process or a selective dry etch process. In some embodiments, a single etching process is performed to laterally recess the sacrificial layers 206. In some embodiments, the selective and partial recess of the sacrificial layers 206 include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

After the recesses 232 are formed, the top surface 232a of each of the recesses 232 is defined by the exposed bottom portion of a channel layer 208 over the recess 232, and the bottom surface 232b of each of the recesses 232 is defined by the exposed top portion of another channel layer 208 underlying the recess 232. As shown in FIG. 3D, the top surface 232a of the recess 232 is not parallel to the bottom surface 232b of the recess 232. In some embodiments, each of the recesses 232 has an increasing vertical dimension toward the source/drain trenches 220. Thus, the inner spacers subsequently formed in the recesses 232 may function as barriers to prevent formation of undesirable seams by etching through the channel layers during the etching process for channel release. In some embodiments, the vertical dimension DRA of the recess 232 (e.g., in the D3 direction) is greater than the vertical dimension DRB of the recess 232 (e.g., in the D3 direction). In some embodiments, the vertical dimension DRB of the recess 232 is substantially equal to the thickness Ts of one of the sacrificial layers 206.

Next, in some embodiments, referring to FIG. 3E to FIG. 3I, method 100 includes a block 110 where inner spacers 240 are formed in the recesses 232. Operation at block 110 may include suitable deposition and etch processes for forming an inner spacer in one of the recesses 232 includes a middle dielectric portion 242 and a shield dielectric portion 240-1 that covers the surfaces of the middle dielectric portion 242. In addition, in some embodiments, the dielectric constant of the shield dielectric portion 240-1 is greater than the dielectric constant of the middle dielectric portion 242, which will be described in more detail below.

Referring to FIG. 3E, in some embodiments, a first dielectric material layer 2410 is conformally deposited on the sidewalls and a bottom of the source/drain trench 220. Specifically, as shown in FIG. 3E, the first dielectric material layer 2410 is conformally deposited on the exposed sidewalls 218s of the gate spacer layer 218, the exposed sidewalls 208s of the channel layers 208, the exposed sidewalls 206s of the sacrificial layers 206 and the bottom of the source/drain trench 220. Also, the first dielectric material layer 2410 is conformally deposited on the exposed inner sidewalls of the recesses 232. After the first dielectric material layer 2410 is deposited, the original spaces of the recesses 232 are occupied by parts of the first dielectric material layer 2410, and the remaining spaces in the recesses 232 are referred to as first cavities 234. In some embodiments, the thickness T1 of the first dielectric material layer 2410 that is deposited in the source/drain trench 220 and the recesses 232 is substantially uniform.

In some embodiments, the first dielectric material layer 2410 includes one or more materials that have non-low dielectric constant (non-low-k). Specifically, the first dielectric material layer 2410 may have a dielectric constant of about 3.0 to about 8.0, or about 3.0 to about 7.5, or about 3.0 to about 7.0, or about 3.0 to about 6.5, or about 3.0 to about 6.0. In some embodiments, the first dielectric material layer 2410 has a dielectric constant of about 5.0 to about 8.0, or about 5.0 to about 7.5, or about 5.0 to about 7.0, or about 5.0 to about 6.5, or about 5.0 to about 6.0. In some embodiments, the first dielectric material layer 2410 has a dielectric constant of about 5, or another suitable dielectric constant. Those numerical values are provided for exemplification purposes only and are not intended to be limiting.

In addition, in some embodiments, the first dielectric material layer 2410 includes silicon, oxygen and at least one of carbon and nitrogen.

In some embodiments where the first dielectric material layer 2410 includes carbon, the carbon concentration ([C]) is less than about 15%.

In some embodiments where the first dielectric material layer 2410 includes nitrogen, the nitrogen concentration ([N]) is in a range of about 15% to about 30%.

In some embodiments where the first dielectric material layer 2410 includes oxygen, the oxygen concentration ([O]) is in a range of about 30% to about 50%.

In some embodiments where the first dielectric material layer 2410 includes carbon, oxygen, and other element(s), the carbon concentration ([C]) is less than about 15%, and the oxygen concentration is in a range of about 30% to about 50%.

In some embodiments where the first dielectric material layer 2410 includes nitrogen, oxygen, and other element(s), the nitrogen concentration ([N]) is in a range of about 15% to about 30%, and the oxygen concentration ([O]) is in a range of about 30% to about 50%.

In some embodiments where the first dielectric material layer 2410 includes nitrogen, carbon, oxygen, and other element(s), the nitrogen concentration ([N]) is in a range of about 15% to about 30%, the carbon concentration ([C]) is less than about 15%, and the oxygen concentration ([O]) is in a range of about 30% to about 50%.

In some embodiments, the total concentrations of nitrogen and carbon are less than the concentration of oxygen ([O]) in the first dielectric material layer 2410, and can be represented as nitrogen ([N])+carbon ([C])<oxygen ([O]).

In some embodiments, a comparison between the concentrations of carbon ([C]), nitrogen ([N]), silicon ([Si]), and oxygen ([O]) in the first dielectric material layer 2410 can be represented as:

Carbon ([C])<nitrogen ([N])<silicon ([Si])<oxygen ([O]).

In some implementations, the first dielectric material layer 2410 includes nitrogen in an amount of about 15% to about 30% and oxygen in an amount of less than 50%, allowing the first dielectric material layer 2410 to be referred to as a hard film for forming a portion of an inner spacer of some embodiments.

In some embodiments, the first dielectric material 2410 includes one or more non-low-k dielectric materials, such as silicon nitride, silicon oxynitride, and silicon carbonitride, or any other suitable dielectric material. In some implementations, the first dielectric material 2410 is deposited using CVD, plasma-enhanced chemical vapor deposition (PECVD), SACVD, ALD, or another suitable method. In one embodiment, the first dielectric material 2410 is deposited using ALD.

Next, referring to FIG. 3F, in some embodiments, a second dielectric material layer 2420 is conformally deposited on the first dielectric material layer 2410, wherein the second dielectric material layer 2420 is deposited in the first cavities 234 (FIG. 3E). In some embodiments, the second dielectric material layer 2420 is conformally deposited on the first dielectric material layer 2410 and has a similar cross-sectional shape as the first dielectric material layer 2410. After the second dielectric material layer 2420 is deposited, spaces of the first cavities 234 are occupied by parts of the second dielectric material layer 2420, and the remaining spaces in the first cavities 234 are referred to as second cavities 236. The second cavities 236 are recessed between adjacent vertically stacked channel layers 208.

In some embodiments, the thickness T2 of the second dielectric material layer 2420 that is deposited in the source/drain trench 220 and the first cavities 234 in the recesses 232 is substantially uniform. In some embodiments, a thickness ratio of the thickness T2 to the thickness T1 is at least 2 or greater than 2, approximately. In some embodiments, a thickness ratio of the thickness T2 to the thickness T1 is in a range of about 2 to about 3. In some embodiments, a thickness ratio of the thickness T2 to the thickness T1 is about 2.

In addition, according to the embodiments, the dielectric constant of the second dielectric material layer 2420 is less than the dielectric constant of the first dielectric material layer 2410.

In some embodiments, the second dielectric material layer 2420 includes one or more low-k dielectric materials. Specifically, the second dielectric material layer 2420 has a dielectric constant (k value) of about 3.9 or less. In some embodiments, the second dielectric material layer 2420 has a dielectric constant of about 2.0 to about 3.9. In some embodiments, the second dielectric material layer 2420 has a dielectric constant of about 2.0 to about 3.5. In some embodiments, the second dielectric material layer 2420 has a dielectric constant of about 2.0 to about 3.0. In some embodiments, the second dielectric material layer 2420 has a dielectric constant of about 2.5 to about 3.9. In some embodiments, the second dielectric material layer 2420 may have a dielectric constant of about 3.0 to about 3.9. In some embodiments, the second dielectric material layer 2420 has a dielectric constant of about 3, or another suitable dielectric constant. Those numerical values are provided for exemplification purposes only and are not intended to be limiting.

In addition, in some embodiments, the second dielectric material layer 2420 includes silicon, oxygen, and optionally carbon and/or nitrogen.

In some embodiments where the second dielectric material layer 2420 includes carbon and other element(s), the carbon concentration ([C]) is less than about 10%.

In some embodiments where the second dielectric material layer 2420 includes nitrogen, the nitrogen concentration ([N]) is less than about 10%.

In some embodiments where the second dielectric material layer 2420 includes oxygen, the oxygen concentration ([O]) is greater than about 50%.

In some embodiments where the second dielectric material layer 2420 includes nitrogen, carbon, oxygen, and other element(s), the nitrogen concentration ([N]) is less than about 10%, the carbon concentration ([C]) is less than about 10%, and the oxygen concentration ([O]) is greater than about 50%.

In some embodiments, the total concentrations of nitrogen and carbon are less than the concentration of oxygen ([O]) of the second dielectric material layer 2420, and can be represented as nitrogen ([N])+carbon ([C])<oxygen ([O]).

In some embodiments, the total concentrations of nitrogen, carbon and silicon of the second dielectric material layer 2420 are less than the concentration of oxygen ([O]) of the second dielectric material layer 2420, and can be represented as:

Nitrogen ([N])+carbon ([C])+nitrogen ([Si]<oxygen ([O]).

In some embodiments, the second dielectric material layer 2420 includes oxygen in an amount of greater than 50%, nitrogen and/or carbon in an amount of less than about 10%, allowing the second dielectric material layer 2420 to be referred to as a soft film.

In some embodiments, the second dielectric material layer 2420 includes one or more low-k dielectric materials selected from the group consisting of porous silicon dioxide, carbon doped silicon dioxides, fluorine doped silicon dioxide, and another suitable low-k (e.g., k<3.9) dielectric material. In some implementations, the second dielectric material layer 2420 is deposited using CVD, plasma-enhanced chemical vapor deposition (PECVD), SACVD, ALD, or another suitable method. In one embodiment, the second dielectric material layer 2420 is deposited using ALD.

Next, referring to FIG. 3G, in some embodiments, a portion of the second dielectric material layer 2420 is removed, and remaining portions of the second dielectric material layer 2420 in the recesses 232 form middle dielectric portions 242. In some embodiments, the second dielectric material layer 2420 is selectively etched to expose the first dielectric material layer 2410 on the sidewall 218s of the gate spacer layer 218 and on the sidewalls 208s of the channel layers 208.

In addition, as shown in FIG. 3G, the side surface 242S1, the top surface 242a, and the bottom surface 242b of each of the middle dielectric portions 242 are covered by the first dielectric material layer 2410, while the side surfaces 242S2 of the middle dielectric portions 242 in the recesses 232 are exposed and face the source/drain trench 220.

Next, referring to FIG. 3H, in some embodiments, a third dielectric material layer 2430 is conformally deposited in the source/drain trench 220. Specifically, the third dielectric material layer 2430 is deposited on the first dielectric material layer 2410 and covers the middle dielectric portions 242.

In some embodiments, the third dielectric material layer 2430 includes one or more materials that have non-low dielectric constant (non-low-k). Specifically, the third dielectric material layer 2430 may have a dielectric constant of about 3.0 to about 8.0, or about 3.0 to about 7.5, or about 3.0 to about 7.0, or about 3.0 to about 6.5, or about 3.0 to about 6.0. In some embodiments, the third dielectric material layer 2430 has a dielectric constant of about 5.0 to about 8.0, or about 5.0 to about 7.5, or about 5.0 to about 7.0, or about 5.0 to about 6.5, or about 5.0 to about 6.0. In some embodiments, the third dielectric material layer 2430 has a dielectric constant of about 5, or another suitable dielectric constant. Those numerical values are provided for exemplification purposes only and are not intended to be limiting.

In some embodiments, the third dielectric material layer 2430 includes one or more non-low-k dielectric materials, such as silicon nitride, silicon oxynitride, and silicon carbonitride, or any other suitable dielectric material. In some implementations, the third dielectric material layer 2430 is deposited using CVD, plasma-enhanced chemical vapor deposition (PECVD), SACVD, ALD, or another suitable method. In one embodiment, the third dielectric material layer 2430 is deposited using ALD.

In addition, in some embodiments, the third dielectric material layer 2430 includes silicon, oxygen and at least one of carbon and nitrogen.

In some embodiments where the third dielectric material layer 2430 includes carbon, the carbon concentration ([C]) is less than about 15%.

In some embodiments where the third dielectric material layer 2430 includes nitrogen, the nitrogen concentration ([N]) is in a range of about 15% to about 30%.

In some embodiments where the third dielectric material layer 2430 includes oxygen, the oxygen concentration ([O]) is in a range of about 30% to about 50%.

In some embodiments where third dielectric material layer 2430 includes carbon, oxygen, and other element(s), the carbon concentration ([C]) is less than about 15%, and the oxygen concentration is in a range of about 30% to about 50%.

In some embodiments where the third dielectric material layer 2430 includes nitrogen, oxygen, and other element(s), the nitrogen concentration ([N]) is in a range of about 15% to about 30%, and the oxygen concentration ([O]) is in a range of about 30% to about 50%.

In some embodiments where the third dielectric material layer 2430 includes nitrogen, carbon, oxygen, and other element(s), the nitrogen concentration ([N]) is in a range of about 15% to about 30%, the carbon concentration ([C]) is less than about 15%, and the oxygen concentration ([O]) is in a range of about 30% to about 50%.

In some embodiments, the total concentrations of nitrogen and carbon are less than the concentration of oxygen ([O]) in the third dielectric material layer 2430, and can be represented as nitrogen ([N])+carbon ([C])<oxygen ([O]).

In some embodiments, a comparison between the concentrations of carbon ([C]), nitrogen ([N]), silicon ([Si]), and oxygen ([O]) in the third dielectric material layer 2430 can be represented as:

Carbon ([C])<nitrogen ([N])<silicon ([Si])<oxygen ([O]).

In some implementations, the third dielectric material layer 2430 includes nitrogen in an amount of about 15% to about 30% and oxygen in an amount of less than 50%, allowing the third dielectric material layer 2430 to be referred to as another hard film for forming another portion of an inner spacer of some embodiments.

In addition, in some embodiments, the third dielectric material layer 2430 and the first dielectric material layer 2410 include the same elements that have the same concentration or different concentrations. For example, the third dielectric material layer 2430 and the first dielectric material layer 2410 may include silicon, oxygen and at least one of carbon and nitrogen, and the third dielectric material layer 2430 and the first dielectric material layer 2410 have different oxygen concentrations that are less than about 50%, or in a range of about 30% to about 50%. In addition, in some embodiments, the third dielectric material layer 2430 and the first dielectric material layer 2410 include different combinations of the elements, wherein the third dielectric material layer 2430 and the first dielectric material layer 2410 exhibit characteristics of hard films.

In addition, in some embodiments, the third dielectric material layer 2430 and the first dielectric material layer 2410 include different non-low-k dielectric materials that have dielectric constants of greater than about 3.0 (e.g., about 3.0 to about 8.0) or greater than about 5.0 (e.g., about 5.0 to about 8.0). In some embodiments, the third dielectric material layer 2430 and the first dielectric material layer 2410 include the same non-low-k dielectric material that has dielectric constants of about 3.0 (e.g., about 3.0 to about 8.0) or greater than about 5.0 (e.g., about 5.0 to about 8.0).

Next, referring to FIG. 3I, in some embodiments, portions of the first dielectric material layer 2410 and portions of the third dielectric material layer 2430 are removed by etching, and the sidewall 218s of the gate spacer layer 218 and the sidewalls 208s of the channel layers 208 are exposed in the source/drain trench 220. The remaining portions of the first dielectric material layer 2410 form inner dielectric segments 241 in the respective recesses 232. The remaining portions of the third dielectric material layer 2430 form outer dielectric segments 243. The outer dielectric segments 243 function as seal components to cover the middle dielectric portions 242.

In addition, in some embodiments, the inner spacers 240 have the sidewalls 240S2 that are substantially flush with the sidewalls 208s of the channel layers 208. In the exemplary embodiment, the sidewalls 240S2 of the inner spacers 240 are substantially flush with the sidewall 218s of the gate spacer layer 218. Specifically, the side surfaces 241S2 of the inner dielectric segments 241 are substantially flush with the side surfaces 243S2 of the outer dielectric segments 243. The side surface 243S2 of the outer dielectric segments 243 and the side surface 241S2 of an inner dielectric segment 241 are collectively referred to as a side surfaces 240S2 of an inner spacer 240. It is noted that the sidewalls 240S2 can be also referred to as the second surfaces 240S2 of the inner spacers 240 in the later description, as shown in FIG. 3O.

As shown in FIG. 3I, in some embodiments, the inner dielectric segment 241 and the outer dielectric segment 243 are collectively referred to as a shield dielectric portion 240-1 that covers the surfaces of the middle dielectric portion 242. The shield dielectric portion 240-1 and the middle dielectric portion 242 are collectively referred to as an inner spacer 240 between adjacent channel layers 208.

In some embodiments, the dielectric constant of the shield dielectric portion 240-1 is greater than the dielectric constant of the middle dielectric portion 242. That is, the dielectric constant of the inner dielectric segment 241 is greater than the dielectric constant of the middle dielectric portion 242, and the dielectric constant of the outer dielectric segment 243 is greater than the dielectric constant of the middle dielectric portion 242. In addition, the dielectric constant of the inner dielectric segment 241 may be the same or different from the dielectric constant of the outer dielectric segment 243.

In some embodiments, the hardness of the shield dielectric portion 240-1 is greater than the hardness of the middle dielectric portion 242. That is, the hardness of the inner dielectric segment 241 is greater than the hardness of the middle dielectric portion 242, and the hardness of the outer dielectric segment 243 is greater than the hardness of the middle dielectric portion 242. The hardness of the inner dielectric segment 241 may be the same or different from the hardness of the outer dielectric segment 243.

In some embodiments, each of the inner spacers 240 has an increasing vertical dimension toward the source/drain trenches 220. The top surface of one (or each) of the inner spacers 240 is not parallel to the bottom surface of one (or each) of the inner spacers 240. For example, the top surface 242a of one (or each) of the middle dielectric portions 242 is not parallel to the bottom surface 242b of the middle dielectric portion 242. As shown in FIG. 3I, the vertical dimension W1 of the side surface 241S1 of the inner dielectric segment 241 is less than the vertical dimension W2 of the side surface 243S1 of the outer dielectric segment 243. The vertical dimension W2 is less than the vertical dimension W3 of the side surface 243S2 of the outer dielectric segment 243. In addition, the combination of the inner dielectric segment 241 and the outer dielectric segment 243 provides a hard shell to prevent formation of undesirable seams by etching through the channel layers 208 (e.g., along the D1 direction) during the etching process for channel release.

In addition, according to the exemplary method of some embodiments, the inner dielectric segment 241 covers the top surface 243a and the bottom surface 243b of the outer dielectric segment 243. Thus, the junction of the inner dielectric segment 241 and the outer dielectric segment 243 further enhances the etch resistance of the inner spacers 240 in the subsequent processes. For example, the top end portion 240TE and the bottom end portion 204BE of the inner spacer 240 each include a portion of the inner dielectric segment 241 and a portion of the outer dielectric segment 243. When the sacrificial layers 206 are selectively removed by etching to release the channel layers 208, the top end portion 240TE and the bottom end portion 204BE of the inner spacer 240 form thicker sections that include non-low-k dielectric materials and serve as solid barriers to stop the lateral etch. In some embodiments, the top end portion 240TE of the inner spacer 240 is above the level of the top surface 206a of the channel layer 206, and the bottom end portion 204BE of the inner spacer 240 is below the level of the bottom surface 206b of the channel layer 206. Therefore, the top end portion 240TE and the bottom end portion 204BE of the inner spacer 240 effectively prevent the formation of undesirable seams by etching through the channel layers 208 during the channel release process, thereby solving the conventional issue of metal extrusion through the seams to form the leakage paths after a replacement gate is formed. Accordingly, the semiconductor structure manufactured by the method of the embodiments has robust inner spacer 240.

Still referring to FIG. 3I, in some embodiments, the thickness T1 (in the first direction D1) of the inner dielectric segment 241 is less than the thickness T2 (in the first direction D1) of the middle dielectric portion 242, and the thickness T3 (in the first direction D1) of the outer dielectric segment 243 is less than the thickness T2 of the middle dielectric portion 242. In addition, the thickness T1 may be equal to or different from the thickness T3.

In some embodiments, a thickness ratio of the thickness T2 to the thickness T1 is at least 2 or greater than 2, approximately. In some embodiments, a thickness ratio of the thickness T2 to the thickness T1 is in a range of about 2 to about 3. In some embodiments, a thickness ratio of the thickness T3 to the thickness T1 is at least 2 or greater than 2, approximately. In some embodiments, a thickness ratio of the thickness T3 to the thickness T1 is in a range of about 2 to about 3. In some embodiments, the middle dielectric portion 242 includes one or more low-k dielectric materials, and volume of the middle dielectric portion 242 is at least half of the total volume of the inner spacer 240. Thus, the inner spacers 240 of the embodiments have the advantage of reducing the parasitic capacitance between the source/drain features subsequently formed in the source/drain trenches 220 and the gate structures subsequently formed by replacing the sacrificial layers 208.

Referring to FIG. 1, FIG. 3J and FIG. 3K, method 100 includes a block 112 where source/drain features 264 are formed in the source/drain trenches 220. Operation at block 112 may include suitable epitaxial processes for growing base epitaxial layers 262 and the source/drain features 264 over the base epitaxial layers 262, which will be described in more detail below.

Referring to FIG. 3J, in some embodiments, after the inner spacers 240 are formed at opposite ends of the sacrificial layers 206, a base epitaxial layer 262 is deposited in the bottom of each of the source/drain trenches 220. Formation of the base epitaxial layers 262 reduces the depth of the source/drain trenches 220 and facilitates the growth of the source/drain features 264 in the subsequent process.

In some embodiments, the base epitaxial layer 262 includes the same material as the substrate 202 and the channel layers 208, such as silicon (Si), except for a dopant condition (doping element and/or doping concentration). For example, the base epitaxial layer 262 is made of non-doped silicon, the substrate 202 is made of doped silicon, and the channel layers 208 are made of non-doped or doped silicon. In some embodiments, the base epitaxial layer 262 includes the same material as the sacrificial layers 206, such as silicon germanium (SiGe), but with different germanium (Ge) contents. In some other embodiments, the base epitaxial layer 262, the channel layers 208, and the sacrificial layers 206 are made of different semiconductor materials. In various embodiments, the base epitaxial layer 262 is dopant-free, where for example, no intentional doping is performed during the epitaxial growth process. As a comparison, the substrate 202 may be lightly doped and has a higher doping concentration than the base epitaxial layer 262.

In addition, the base epitaxial layer 262 provides a high resistance path from the source/drain regions to the substrate 202, such that the leakage current in the substrate 202 (i.e., through the fin-shaped base 210B) is suppressed. The inner spacers 240 limit the vertical growth of the base epitaxial layer 262, as the epitaxial growth may not take place from a dielectric surface. The base epitaxial layer 262 may exhibit faceted growth when it reaches the bottommost inner spacers 240. Thus, in some embodiments, the base epitaxial layer 262 may partially overlap with a bottom portion of the bottommost inner spacers 240 but does not grow vertically beyond the top surface of the bottommost inner spacers 240. The base epitaxial layer 262, level with the bottom surface of the bottommost inner spacers 240, is depicted in the drawings for the sake of simplicity and clarity.

Suitable epitaxial processes for growing the base epitaxial layer 262 may include vapor-phase epitaxy (VPE), molecular beam epitaxy (MBE), selective CVD, and/or another suitable process. Various deposition parameters can be tuned to selectively deposit the semiconductor material on exposed semiconductor surfaces in the source/drain trenches 220, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the workpiece 200 is exposed to a deposition mixture that includes DCS and/or SiH₄ (silicon-containing precursor), H₂ (carrier precursor), and HCl (etchant-containing precursor) when forming the base epitaxial layer 262. In some embodiments, the selective CVD process implements a deposition temperature of about 600° C. to about 750° C. In some embodiments, the selective CVD process implements a deposition pressure of about 10 Torr to about 100 Torr. In some embodiments, a bottom-up deposition process is performed, such that the base epitaxial layer 262 grows from the exposed semiconductor surface at the bottom of the source/drain trench 220, but not from exposed end portions of the channel layers 208. In some embodiments, a post-deposition etch is performed after the selective CVD process to remove any semiconductor material of the base epitaxial layer 262 that may remain on the end portions of the channel layers 208, if any. The post-deposition etch includes a dry etching, a wet etching, other suitable etching process, or combinations thereof.

Referring to FIG. 3K, in some embodiments, the source/drain features 264 are formed in the source/drain trenches 220. In some embodiments, the source/drain features 264 may also be referred to as doped epitaxial layers 264. Sometimes, the term “source/drain features” includes the doped epitaxial layer 264 and the base epitaxial layer 262 underneath.

In an embodiment, forming the source/drain features 264 includes epitaxially growing the semiconductor layers using an MBE process, a chemical vapor deposition process, and/or other suitable epitaxial growth processes. The source/drain features 264 may include silicon doped with phosphorous or arsenic for n-type transistors. The source/drain features 264 may include silicon germanium doped with boron for p-type transistors. The source/drain features 264 cover the base epitaxial layers 262 and are in contact with the inner spacers 240. In addition, the source/drain features 264 are in contact with the sidewalls 208s of the channel layers 208. The source/drain features 264 may grow vertically beyond the top surfaces of the topmost inner spacers 240 and the topmost channel layer 208.

In some embodiments, when the processes for forming the base epitaxial layers 262 and the source/drain features 264 are performed, the outer dielectric segments 243 of the inner spacers 240, which has a higher dielectric constant and a greater hardness than the middle dielectric portion 242, prevents the source/drain etch process damage.

Next, referring to FIG. 1, FIG. 3L FIG. 3M, FIG. 3N and FIG. 3O, method 100 includes a block 114 where further processes are performed. Such further processes may include, for example, deposition of a contact etch stop layer (CESL) 266 over the structure and deposition of an interlayer dielectric (ILD) layer 268 over the CESL 266 (shown in FIG. 3L), removal of the dummy gate stacks 215 (shown in FIG. 3M), selective removal of the sacrificial layers 206 in the channel regions to release the channel layers 208 as channel members (shown in FIG. 3N), and formation of gate structures 274 over the channel regions (shown in FIG. 3O). Those components, materials and manufacturing methods in some exemplary embodiments will be described in more detail below.

In some embodiments, the CESL 266 is formed prior to forming the ILD layer 268. The CESL 266 may include silicon nitride, silicon oxynitride, and/or another material known in the art. The CESL 266 may be formed by an ALD process, a plasma-enhanced chemical vapor deposition (PECVD) process and/or another suitable deposition process. As shown in FIG. 3L, the CESL 266 is formed on the top surface 264a of the source/drain feature 264.

The ILD layer 268 is then deposited over the CESL 266. In some embodiments, the thickness of the CESL 266 along the first direction D1 is less than the thickness of the ILD layer 268. In addition, the source/drain feature that includes the doped epitaxial layer 264 and the base epitaxial layer 262 underneath is partially embedded in the substrate 202 and beneath the ILD layer 268. The ILD layer 268 may include materials such as tetraethylorthosilicate (TEOS) oxide, undoped silicate glass, or doped silicon oxide such as borophosphosilicate glass (BPSG), fused silica glass (FSG), phosphosilicate glass (PSG), boron-doped silicon glass (BSG), and/or another suitable dielectric material. The ILD layer 268 may be deposited by a PECVD process or another suitable deposition technique. In some embodiments, after formation of the ILD layer 268, the structure may be annealed to improve the integrity of the ILD layer 268. After the deposition of the CESL 266 and the ILD layer 268, a planarization process is performed on the ILD layer 268 and the CESL 266 to remove excess portions over the top surfaces of the dummy gate stacks 215, thereby exposing the dummy gate stacks 215. The planarization process may include a chemical mechanical planarization (CMP) process. Exposure of the dummy gate stacks 215 allows the removal of the dummy gate stacks 215 and release of the channel layers 208.

In some embodiments, the dielectric constant of the CESL 266 is greater than the dielectric constant of the ILD layer 268. In some embodiments, the dielectric constant of the shield dielectric portion 240-1 is greater than the dielectric constant of the ILD layer 268. In addition, the dielectric constant of the shield dielectric portion may be the same as the dielectric constant of the CESL, or greater than the dielectric constant of the CESL.

In some embodiments, as shown in FIG. 3M, the exposed dummy gate stacks 215 are removed to form gate trenches 270 over the channel layers 208. The removal of the dummy gate stacks 215 may include one or more etching processes that are selective to the material of the dummy gate stack 215. For example, the removal of the dummy gate stacks 215 may be performed using a selective wet etch, a selective dry etch, or a combination thereof that is selective to the dummy gate stacks 215. After the removal of the dummy gate stacks 215, the sidewalls of the channel layers 208 and the sacrificial layers 206 in the channel region are exposed in the gate trenches 270.

In some embodiments, as shown in FIG. 3N, after the removal of the dummy gate stacks 215, the method 100 may include an operation to selectively remove the sacrificial layers 206 between the channel layers 208. The selective removal of the sacrificial layers 206 releases the channel layers 208 to form channel members (also numbered as 208). In addition, the selective removal of the sacrificial layers 206 leaves behind space 272 between the channel members 208. The selective removal of the sacrificial layers 206 may be implemented by selective dry etch, selective wet etch, or another selective etch process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

In some embodiments, as shown in FIG. 3O, the method 100 may include further operations to form a gate structure 274 to wrap around each of the channel members 208. In some embodiments, the gate structure 274 is formed within the gate trench 270 and into the space 272 left behind by the removal of the sacrificial layers 206. In some embodiments, the gate structure 274 is in contact with the inner dielectric segments 241 of the inner spacers 240.

In some embodiments, the gate structure 274 includes a gate dielectric layer 275 and a gate electrode layer 277 over the gate dielectric layer 275. The gate dielectric layer 275 may include one or more high-K gate dielectric materials. In some embodiments, the dielectric constant of the gate dielectric layer 275 is greater than the dielectric constant of the inner dielectric segment 241. In some embodiments, the dielectric constant of the gate dielectric layer 275 is greater than the dielectric constant of the outer dielectric segment 243. In addition, in some embodiments, the middle dielectric portion 242 includes one or more low-k dielectric materials, and the volume of the middle dielectric portion 242 is more than half of the total volume of the inner spacer 240. Thus, the inner spacers 240 of the embodiments have the advantages of preventing etch damage and reducing the parasitic capacitance between the source/drain feature 264 and the gate structure 274.

High-K dielectric materials for forming the gate dielectric layer 275 may include dielectric materials having a high dielectric constant greater than that of thermal silicon oxide (about 3.9). The high-K gate dielectric layer may include hafnium oxide, titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or another suitable method. In one embodiment, the gate dielectric layer 275 is formed using a highly conformal deposition process such as ALD in order to ensure the formation of a gate dielectric layer having a uniform thickness around each channel layer 208.

In addition, while not explicitly shown in the figures, the gate dielectric layer 275 may include an interfacial layer and a high-K gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or another suitable method.

The gate electrode layer 277 of the gate structure 274 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, and/or combinations thereof. The gate electrode layer 277 may be formed by ALD, PVD, CVD, e-beam evaporation, or another suitable process. In some embodiments, a gate dielectric material layer and a gate electrode material layer are deposited over the top surface 266a of the CESL 266 and the top surface 268a of the ILD layer 268. Excessive amounts of the gate dielectric material layer and the gate electrode material layer formed over the ILD layer 268 are then planarized using, for example, a CMP process, until the CESL 266 and the ILD layer 268 are exposed. Thus, the gate structure 274 may provide a substantially planar top surface. In addition, the gate structure 274 includes portions that interpose between the channel members 208 in the channel region.

In some embodiments, the gate structure 274 further includes a work function adjustment layer 276 disposed between the gate dielectric layer 275 and the gate electrode layer 277 to enhance the device performance. The work function adjustment layer 276 may include one or more work function metal layers. In some embodiments, the work function adjustment layer 276 is made of one or more conductive materials, such as a single layer of TiN, TaN, TaAlC, TiC, TaC, Co, Al, TiAl, HfTi, TiSi, TaSi, or TiAlC, or a multilayer of two or more of these materials. The work function adjustment layer 276 may be formed by ALD, PVD, CVD, e-beam evaporation, or another suitable process.

According to the aforementioned descriptions, the semiconductor structure 200, in accordance with some embodiments, have several advantages. In some embodiments, when the sacrificial layers 206 are selectively removed by etching to release the channel layers 208 (FIG. 3N), the inner dielectric segments 241 of the inner spacers 240, which has a higher dielectric constant and a greater hardness than the middle dielectric portion 242, prevents the channel release damage, resulting in the improvement of the reliability of the semiconductor structure 200.

In some embodiments, the inner spacers 240 that are formed by the exemplary method above have trapezoidal-like cross sections, which prevents the formation of undesirable leakage paths between the gate structure 274 and the source/drain feature 264, so as to facilitate the improvement of the reliability of the semiconductor structure 200. Specifically, as shown in FIG. 3O, one or each of the inner spacers 240 has a first surface 240Sl adjacent to the gate structure 274 and a second surface 240S2 adjacent to the source/drain feature 264. The first surface 240S1 may be in contact with the gate structure 274, and the second surface 240S2 may be in contact with the source/drain feature 264. In some embodiments, the first surface 240S1 has an inner dimension DA, and the second surface 240S2 has an outer dimension DB. The inner dimension DA of the inner spacers 240 may be substantially equal to or greater than the thickness Tg of the portion of the gate structure 274 between two adjacent channel members 208. The outer dimension DB is greater than the inner dimension DA. Therefore, the junctions of the inner dielectric segment 241 and the outer dielectric segment 243 (i.e., the top end portion 240TE of the inner spacer 240 above the level of the top surface 206a of the channel layer 206 and the bottom end portion 240BE of the inner spacer 240 below the level of the bottom surface 206b of the channel layer 206, as described above) further enhances the etch resistance of the inner spacers 240 in the subsequent processes.

In addition, in some embodiments, the middle dielectric portion 242 includes one or more low-k dielectric materials, and the dielectric constant of the middle dielectric portion 242 is less than the dielectric constant of a thin shell formed by the inner dielectric segment 241 and the outer dielectric segment 243. In addition, the volume of the middle dielectric portion 242 is more than half of the total volume of the inner spacer 240. Thus, the inner spacers 240 of the embodiments have the advantage of reducing the parasitic capacitance between the source/drain features 264 subsequently formed in the source/drain trenches 220 and the gate structures 274 subsequently formed by replacing the sacrificial layers 206.

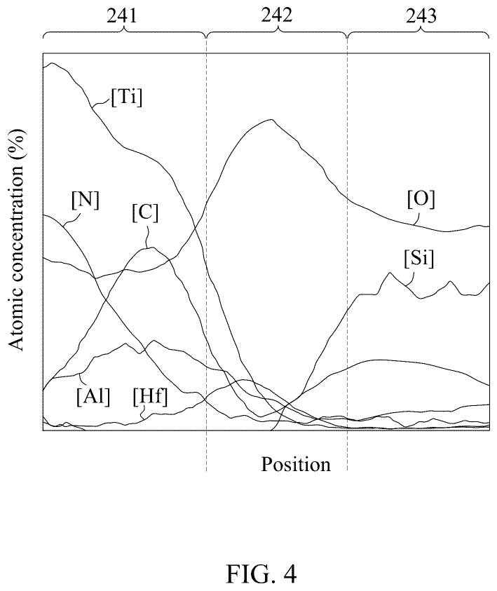

FIG. 4 is energy dispersion X-ray spectrum (EDX) analysis of the relative concentrations of several atomic species versus positions of the inner spacers of exemplary structure, in accordance with some embodiments.

Analysis shows the respective concentrations of oxygen [O], nitrogen [N], carbon [C], silicon [Si], titanium [Ti], aluminum [Al] and hafnium [Hf] versus positions of the inner dielectric segment 241, the middle dielectric portion 242 and the outer dielectric segment 243 of the inner spacers 240. As shown in EDX analysis, the middle dielectric portion 242 is an oxygen-rich portion, and can be regarded as a porous film. The peak of oxygen signal in the EDX profile is located within the middle dielectric portion 242. As shown in EDX analysis, the inner dielectric segment 241 and the outer dielectric segment 243 each have carbon concentrations greater than the middle dielectric portion 242. In addition, the middle dielectric portion 242 is relatively lower in nitrogen concentration than the inner dielectric segment 241 and the outer dielectric segment 243. The inner dielectric segment 241 and the outer dielectric segment 243 of the inner spacers can be referred to as hard films with one or more non-low-k dielectric materials, while the middle dielectric portion 242 can be referred to as a porous film with one or more low-k dielectric material, in accordance with some embodiments.

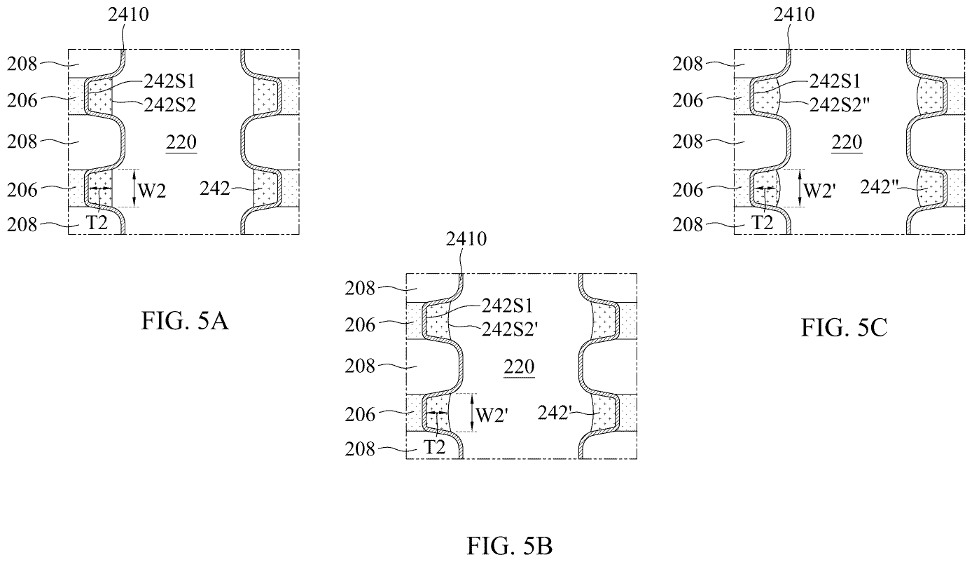

FIG. 5A, FIG. 5B, and FIG. 5C are fragmentary cross-sectional views illustrating semiconductor structures at an intermediate stage after forming the middle dielectric portions of the inner spacers, in accordance with some embodiments of the present disclosure.

FIG. 5A is a partially enlarged cross-sectional view of the middle dielectric portions 242 of FIG. 3G. The features/components in FIG. 5A that are identical to the features/components in FIG. 3G are designated with the same reference numbers. Details of the arrangement, materials, and manufacturing methods of those similar or identical features/components shown in FIG. 5A are essentially the same as those discussed with reference to FIG. 3A to FIG. 3G, and are not repeated herein.

In some embodiments, the middle dielectric portion 242 includes the side surface 242S1 in contact with the first dielectric material layer 2410, and the side surface 242S2 that is exposed and faces the source/drain trench 220. The side surface 242S2 is a flat surface, and substantially vertical to the extending direction (e.g., the D1 direction) of the channel layers 208. In some embodiments, the middle dielectric portion 242 is at least twice as thick as the first dielectric material layer 2410, which will be patterned later to form the inner dielectric segments 241 in FIG. 3I. The thickness of the middle dielectric portion 242 can be measured from a distance between the side surfaces 242S1 and 242S2 in the D1 direction. The thicker the middle dielectric portion 242, the greater the reduction in parasitic capacitance between the source/drain features 264, which are subsequently formed in the source/drain trenches 220, and the gate structures 274, which are formed by replacing the sacrificial layers 206, as shown in FIG. 3O.

FIG. 5B is an alternative embodiment illustrating the middle dielectric portions 242′. The features/components in FIG. 5B that are similar or identical to the features/components in FIG. 5A are designated with similar or the same reference numbers. Details of the arrangement, materials, and manufacturing methods of those similar or identical features/components shown in FIG. 5B are essentially the same as those discussed with reference to FIG. 3A to FIG. 3G, and are not repeated herein.

In some embodiments, the middle dielectric portion 242′ includes the side surface 242S1 in contact with the first dielectric material layer 2410, and the side surface 242S2′ that is exposed and faces the source/drain trench 220. The differences between the middle dielectric portion 242 in FIG. 5A and the middle dielectric portion 242′ in FIG. 5B is that the side surface 242S2′ in FIG. 5B is a concave side surface. The concave side surface 242S2′ has a vertical dimension W2′ extending between two adjacent channel layers 208. The vertical dimension W2′ in FIG. 5B is greater than the vertical dimension W2 in FIG. 5A. That is, when comparing the middle dielectric portion 242 in FIG. 5A and the middle dielectric portion 242′ in FIG. 5B (both have the same thickness T2 along a virtual central line in the D1 direction), the middle dielectric portion 242′ with the concave side surface 242S2′ has a greater volume. This further reduces the parasitic capacitance between the source/drain features 264, which are subsequently formed in the source/drain trenches 220, and the gate structures 274, which are formed by replacing the sacrificial layers 206.

FIG. 5C is an alternative embodiment illustrating the middle dielectric portions 242″. The features/components in FIG. 5C that are similar or identical to the features/components in FIG. 5A are designated with similar or the same reference numbers. Details of the arrangement, materials, and manufacturing methods of those similar or identical features/components shown in FIG. 5C are essentially the same as those discussed with reference to FIG. 3A to FIG. 3G, and are not repeated herein.

In some embodiments, the middle dielectric portion 242″ includes the side surface 242S1 in contact with the first dielectric material layer 2410, and the side surface 242S2″ that is exposed and faces the source/drain trench 220. The differences between the middle dielectric portion 242 in FIG. 5A and the middle dielectric portion 242″ in FIG. 5C is that the side surface 242S2″ in FIG. 5C is a convex side surface. In this exemplary embodiment, the convex side surface 242S2″ in FIG. 5C and the concave side surface 242S2′ in FIG. 5B have the same vertical dimension W2′ extending between two adjacent channel layers 208. When comparing the middle dielectric portion 242″ in FIG. 5C to the middle dielectric portion 242 in FIG. 5A and the middle dielectric portion 242′ in FIG. 5B, it is observed that the middle dielectric portion 242″ with the convex side surface 242S2″ has a greater volume. This further reduces the parasitic capacitance between the source/drain features 264, which are subsequently formed in the source/drain trenches 220, and the gate structures 274, which are formed by replacing the sacrificial layers 206.

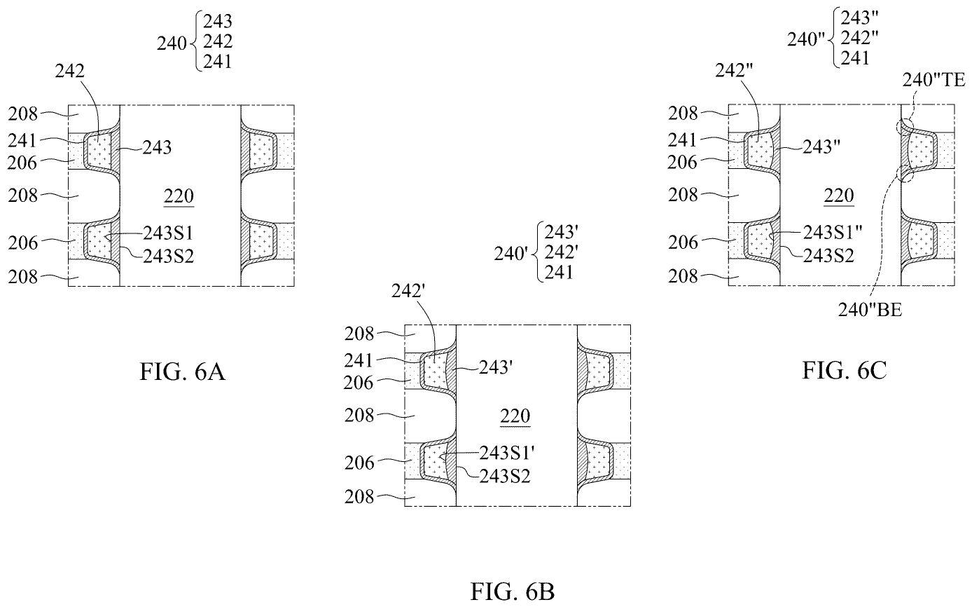

FIG. 6A, FIG. 6B, and FIG. 6C are fragmentary cross-sectional views illustrating semiconductor structures at an intermediate stage after forming the inner spacers, in accordance with some embodiments of the present disclosure.

FIG. 6A is a partially enlarged cross-sectional view of the inner spacers 240 of FIG. 3I. The features/components in FIG. 6A that are identical to the features/components in FIG. 3I are designated with the same reference numbers. Details of the arrangement, materials, and manufacturing methods of those similar or identical features/components shown in FIG. 6A are essentially the same as those discussed with reference to FIG. 3A to FIG. 3I, and are not repeated herein.

In some embodiments, each of the inner spacers 240 includes an inner dielectric segment 241, a middle dielectric portion 242, and an outer dielectric segment 243. In some embodiments, the outer dielectric segment 243 includes the side surface 243S1 in contact with the middle dielectric portion 242, and the side surface 243S2 that is exposed and faces the source/drain trench 220. The side surfaces 243S1 and 243S2 are flat surfaces, and substantially vertical to the extending direction (e.g., the D1 direction) of the channel layers 208. In some embodiments, the middle dielectric portion 242 is at least twice as thick as the inner dielectric segment 241, and at least twice as thick as the outer dielectric segment 243. The thicker the middle dielectric portion 242, the greater the reduction in parasitic capacitance between the source/drain features 264, which are subsequently formed in the source/drain trenches 220, and the gate structures 274, which are formed by replacing the sacrificial layers 206, as shown in FIG. 3O. In addition, the thicker the outer dielectric segment 243, the greater the resistance to prevent damage from the source/drain etch process.

FIG. 6B is an alternative embodiment illustrating the inner spacers 240′. The features/components in FIG. 6B that are identical to the features/components in FIG. 6A are designated with the same reference numbers. Details of the arrangement, materials, and manufacturing methods of those similar or identical features/components shown in FIG. 6B are essentially the same as those discussed with reference to FIG. 3A to FIG. 3I, and are not repeated herein.

In some embodiments, each of the inner spacers 240′ includes an inner dielectric segment 241, a middle dielectric portion 242′, and an outer dielectric segment 243′. In some embodiments, the outer dielectric segment 243′ includes the side surface 243S1′ in contact with the middle dielectric portion 242′, and the side surface 243S2 that is exposed and faces the source/drain trench 220. The side surface 243S1′ is a convex surface, and the side surface 243S2 is a flat surface. As shown in FIG. 6B, the outer dielectric segment 243′ has a thicker middle section that improves the resistance to prevent damage from the source/drain etch process.

FIG. 6C is an alternative embodiment illustrating the inner spacers 240″. The features/components in FIG. 6C that are identical to the features/components in FIG. 6A are designated with the same reference numbers. Details of the arrangement, materials, and manufacturing methods of those similar or identical features/components shown in FIG. 6C are essentially the same as those discussed with reference to FIG. 3A to FIG. 3I, and are not repeated herein.

In some embodiments, each of the inner spacers 240″ includes an inner dielectric segment 241, a middle dielectric portion 242″, and an outer dielectric segment 243″. In some embodiments, the outer dielectric segment 243″ includes the side surface 243S1″ in contact with the middle dielectric portion 242″, and the side surface 243S2 that is exposed and faces the source/drain trench 220. The side surface 243S1″ is a concave surface, and the side surface 243S2 is a flat surface. As shown in FIG. 6C, the outer dielectric segment 243″ has thicker ends, resulting in the thicker junctions of the inner dielectric segment 241 and the outer dielectric segment 243″, such as the top end portion 240″TE and the bottom end portion 240″BE of the inner spacer 240″ as described above. In some embodiments, the top end portion 240″TE of the inner spacer 240″ is positioned above the level of the top surface 206a of the channel layer 206, and the bottom end portion 240″BE of the inner spacer 240″ is positioned below the level of the bottom surface 206b of the channel layer 206, thereby improving the resistance to prevent damage from the source/drain etch process. In addition, the top end portion 240″TE and the bottom end portion 240″BE of the inner spacer 240″ also preventing the formation of undesirable seams extending to the source/drain features during channel release process and the formation of leakage paths between the metal gate and the source/drain features after a gate structure (e.g., containing a metal gate) is deposited to wrap around the channel layers.

In the implementation, a suitable approach for the configuration of inner spacers can be selected from the exemplary embodiments provided above, based on the conditions of processes, such as the source/drain etch process and the channel release etch process.

Although not intended to be limiting, one or more embodiments of the present disclosure provide many benefits to a semiconductor structure and the formation thereof. For example, embodiments of the present disclosure provide inner spacers interleaving the channel members, and one of the inner spacers includes a middle dielectric portion and a shield dielectric portion that covers the surfaces of the middle dielectric portion. The shield dielectric portion includes an inner dielectric segment and an outer dielectric segment that joins two ends of the inner dielectric segment. In addition, the dielectric constant of the shield dielectric portion is greater than the dielectric constant of the middle dielectric portion. Thus, the outer dielectric segment with a greater dielectric constant effectively prevents damage from the source/drain etch process. The inner dielectric segment with a greater dielectric constant effectively prevents damage from the channel release etch process. Accordingly, the reliability and electrical performance of the semiconductor structure of the embodiments are greatly improved.

In one exemplary aspect, the present disclosure is directed to a semiconductor structure. The semiconductor structure includes channel members disposed above a substrate, a gate structure wrapping around the channel members, inner spacers adjacent to the gate structure, a source/drain feature abutting the channel members, a contact etch stop layer over the source/drain feature, and an interlayer dielectric layer over the CESL. One of the inner spacers includes a middle dielectric portion and a shield dielectric portion that covers surfaces of the middle dielectric portion. The dielectric constant of the shield dielectric portion is greater than the dielectric constant of the middle dielectric portion. The dielectric constant of the CESL is greater than the dielectric constant of the ILD layer.

In some embodiments, the thickness of the middle dielectric portion is greater than the thickness of the shield dielectric portion along the lengthwise direction of the channel members. In some embodiments, the middle dielectric portion and the channel members are separated by the shield dielectric portion. In some embodiments, an oxygen concentration of the middle dielectric portion is greater than an oxygen concentration of the shield dielectric portion. In some embodiments, a combination of a carbon concentration and a nitrogen concentration of the middle dielectric portion is less than a combination of a carbon concentration and a nitrogen concentration of the shield dielectric portion. In some embodiments, the shield dielectric portion includes an inner dielectric segment and an outer dielectric segment. The inner dielectric segment covers the top surface, the inner side surface and the bottom surface of the middle dielectric portion. The inner side surface is positioned adjacent to the gate structure. The outer dielectric segment connects the inner dielectric segment and covers the outer side surface of the middle dielectric portion. In some embodiments, the inner dielectric segment and the outer dielectric segment each have a higher etch resistance than the middle dielectric portion. In some embodiments, the gate structure includes a gate dielectric layer and a metal gate electrode on the gate dielectric layer. The dielectric constant of the inner dielectric segment is less than the dielectric constant of the gate dielectric layer, and the dielectric constant of the outer dielectric segment is less than the dielectric constant of the gate dielectric layer. In some embodiments, the inner dielectric segment covers the top surface and the bottom surface of the outer dielectric segment.

In another exemplary aspect, the present disclosure is directed to a method. The method includes alternately stacking channel layers and sacrificial layers on a substrate in a vertical direction to form a semiconductor stack, patterning the semiconductor stack to form a fin-shaped structure protruding from the substrate, forming a source/drain trench in the fin-shaped structure, laterally recessing the sacrificial layers in the fin-shaped structure to form recesses, forming inner spacers in the recesses, forming a source/drain feature in the source/drain trench, forming a contact etch stop layer over the source/drain feature, and forming an interlayer dielectric (ILD) layer over the CESL. The recesses at opposite ends of one of the sacrificial layers are separated from each other along a direction. The thickness of the CESL along the direction is less than the thickness of the ILD layer. One of the inner spacers includes a middle dielectric portion and a shield dielectric portion covering surfaces of the middle dielectric portion, and a dielectric constant of the shield dielectric portion is greater than a dielectric constant of the middle dielectric portion.

In some embodiments, forming one of the inner spacers includes forming an inner dielectric segment on a sidewall of one of the recesses; forming a middle dielectric portion on the inner dielectric segment in one of the recesses; and forming an outer dielectric segment on the middle dielectric portion in one of the recesses.

In some embodiments, forming the inner spacers includes conformally deposited a first dielectric material layer on exposed sidewalls of the channel layers in the source/drain trench and on sidewalls of the recesses, and the first dielectric material layer defines a first cavity in one of the recesses; conformally deposited a second dielectric material layer on the first dielectric material layer, and the second dielectric material layer are recessed in the first cavities; and removing a portion of the second dielectric material layer, and remaining portions of the second dielectric material layer in the recesses form middle dielectric portions. In some embodiments, a dielectric constant of the first dielectric material layer is greater than a dielectric constant of the second dielectric material. In some embodiments, a remaining space in one of the recesses is referred to as a second cavity after forming the middle dielectric portions, and forming the inner spacers further includes conformally deposited a third dielectric material layer on the first dielectric material layer and the middle dielectric portions, wherein the third dielectric material layer fills the second cavities. In some embodiments, the method further includes removing portions of the third dielectric material layer and portions of the first dielectric material layer, wherein remaining portions of the first dielectric material form inner dielectric segments in the recesses, and remaining portions of the third dielectric material form outer dielectric segments in the recesses. In some embodiments, an oxygen concentration of the middle dielectric portion is greater than an oxygen concentration of the shield dielectric portion.

In yet another exemplary aspect, the present disclosure is directed to a method. The method includes forming a fin-shaped structure including a stack atop a base. The stack includes channel layers interleaved with sacrificial layers. The base protrudes from a substrate. The fin-shaped structure includes a channel region and a source/drain region. The method further includes forming a dummy gate stack over the channel region of the fin-shaped structure, depositing a gate spacer layer over the dummy gate stack, forming a source/drain trench by recessing the source/drain region of the fin-shaped structure, forming a contact etch stop layer over the source/drain feature, and forming an interlayer dielectric (ILD) layer over the CESL. The source/drain feature is partially embedded in the substrate and beneath the ILD layer. The source/drain trench exposes sidewalls of the channel layers and the sacrificial layers. The method further includes selectively and partially recessing the sacrificial layers in the fin-shaped structure to form recesses, forming inner spacers in the recesses, and forming a source/drain feature in the source/drain trench. One of the inner spacers includes a shield layer covering surfaces of a middle layer. The dielectric constant of the shield layer is greater than the dielectric constant of the middle layer.

In some embodiments, the shield layer separates the middle layer of the inner spacer from the source/drain feature. In some embodiments, the method further includes removing the dummy gate stack to release the channel layers, selectively removing the sacrificial layers, and forming a gate structure wrapping around the channel layers. The dielectric constant of a gate dielectric layer of the gate structure is greater than the dielectric constant of the shield layer. In some embodiments, the shield layer separates the middle layers of the inner spacer from the gate dielectric layer of the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
channel members disposed above a substrate;
a gate structure wrapping around the channel members;
inner spacers adjacent to the gate structure, wherein one of the inner spacers comprises a middle dielectric portion and a shield dielectric portion that covers surfaces of the middle dielectric portion, and a dielectric constant of the shield dielectric portion is greater than a dielectric constant of the middle dielectric portion;
a source/drain feature abutting the channel members;
a contact etch stop layer over the source/drain feature; and
an interlayer dielectric (ILD) layer over the CESL, wherein a dielectric constant of the CESL is greater than a dielectric constant of the ILD layer.

2. The semiconductor structure of claim 1, wherein a thickness of the middle dielectric portion is greater than a thickness of the shield dielectric portion along a lengthwise direction of the channel members.

3. The semiconductor structure of claim 1, wherein the middle dielectric portion and the channel members are separated by the shield dielectric portion.

4. The semiconductor structure of claim 1, wherein an oxygen concentration of the middle dielectric portion is greater than an oxygen concentration of the shield dielectric portion.

5. The semiconductor structure of claim 1, wherein a combination of a carbon concentration and a nitrogen concentration of the middle dielectric portion is less than a combination of a carbon concentration and a nitrogen concentration of the shield dielectric portion.

6. The semiconductor structure of claim 1, wherein the shield dielectric portion comprises:
an inner dielectric segment that covers a top surface, an inner side surface and a bottom surface of the middle dielectric portion, wherein the inner side surface is positioned adjacent to the gate structure; and
an outer dielectric segment that connects the inner dielectric segment and covers an outer side surface of the middle dielectric portion.

7. The semiconductor structure of claim 6, wherein the inner dielectric segment and the outer dielectric segment each have a higher etch resistance than the middle dielectric portion.

8. The semiconductor structure of claim 6, wherein the gate structure comprises a gate dielectric layer and a metal gate electrode on the gate dielectric layer, a dielectric constant of the inner dielectric segment is less than a dielectric constant of the gate dielectric layer, and a dielectric constant of the outer dielectric segment is less than the dielectric constant of the gate dielectric layer.

9. The semiconductor structure of claim 6, wherein the inner dielectric segment covers a top surface and a bottom surface of the outer dielectric segment.

10. A method for forming a semiconductor structure, comprising:
alternately stacking channel layers and sacrificial layers on a substrate to form a semiconductor stack;
patterning the semiconductor stack to form a fin-shaped structure protruding from the substrate;
forming a source/drain trench in the fin-shaped structure;
laterally recessing the sacrificial layers in the fin-shaped structure to form recesses, wherein the recesses at opposite ends of one of the sacrificial layers are separated from each other along a direction;
forming inner spacers in the recesses, wherein one of the inner spacers includes a middle dielectric portion and a shield dielectric portion covering surfaces of the middle dielectric portion, and a dielectric constant of the shield dielectric portion is greater than a dielectric constant of the middle dielectric portion;
forming a source/drain feature in the source/drain trench;
forming a contact etch stop layer over the source/drain feature; and
forming an interlayer dielectric (ILD) layer over the CESL,
wherein a thickness of the CESL along the direction is less than a thickness of the ILD layer.

11. The method of claim 10, wherein forming one of the inner spacers comprises:
forming an inner dielectric segment on a sidewall of one of the recesses;
forming the middle dielectric portion on the inner dielectric segment in one of the recesses; and
forming an outer dielectric segment on the middle dielectric portion in one of the recesses, wherein the inner dielectric segment and the outer dielectric segment form the shield dielectric portion.

12. The method of claim 10, wherein forming the inner spacers comprises:
conformally deposited a first dielectric material layer on exposed sidewalls of the channel layers in the source/drain trench and on sidewalls of the recesses, wherein the first dielectric material layer defines first cavities in the recesses; and
conformally deposited a second dielectric material layer on the first dielectric material layer, wherein the second dielectric material layer are recessed in the first cavities; and
removing a portion of the second dielectric material layer, wherein remaining portions of the second dielectric material layer in the recesses form middle dielectric portions.

13. The method of claim 12, wherein a dielectric constant of the first dielectric material layer is greater than a dielectric constant of the second dielectric material.

14. The method of claim 12, wherein a remaining space in one of the recesses is referred to as a second cavity after forming the middle dielectric portions, and forming the inner spacers further comprises:
conformally deposited a third dielectric material layer on the first dielectric material layer and the middle dielectric portions, wherein the third dielectric material layer fills the second cavities.

15. The method of claim 14, further comprising:
removing portions of the third dielectric material layer and portions of the first dielectric material layer to expose the sidewalls of the channel layers,
wherein remaining portions of the first dielectric material form inner dielectric segments in the recesses, and remaining portions of the third dielectric material form outer dielectric segments in the recesses.

16. The method of claim 10, wherein an oxygen concentration of the middle dielectric portion is greater than an oxygen concentration of the shield dielectric portion.

17. A method for forming a semiconductor structure, comprising:
forming a fin-shaped structure including a stack atop a base, the stack comprising channel layers interleaved with sacrificial layers, the base protruding from a substrate, the fin-shaped structure comprising a channel region and a source/drain region;
forming a dummy gate stack over the channel region of the fin-shaped structure;
depositing a gate spacer layer over the dummy gate stack;
forming a source/drain trench by recessing the source/drain region of the fin-shaped structure, wherein the source/drain trench exposes sidewalls of the channel layers and the sacrificial layers;
selectively and partially recessing the sacrificial layers in the fin-shaped structure to form recesses;
forming inner spacers in the recesses, wherein one of the inner spacers includes a shield layer covering surfaces of a middle layer, and a dielectric constant of the shield layer is greater than a dielectric constant of the middle layer; and
forming a source/drain feature in the source/drain trench;
forming a contact etch stop layer over the source/drain feature; and
forming an interlayer dielectric (ILD) layer over the CESL,
wherein the source/drain feature is partially embedded in the substrate and beneath the ILD layer.

18. The method of claim 17, wherein the shield layer separates the middle layer of the inner spacer from the source/drain feature.

19. The method of claim 17, further comprising:
removing the dummy gate stack to release the channel layers;
selectively removing the sacrificial layers; and
forming a gate structure wrapping around the channel layers,
wherein a dielectric constant of a gate dielectric layer of the gate structure is greater than a dielectric constant of the shield layer.

20. The method of claim 19, wherein the shield layer separates the middle layer of the inner spacer from the gate dielectric layer of the gate structure after forming the gate structure.
